(19) United States
(12) Patent Application Publication
(10) Pub. No.: US 2014/0319640 A1
(43) Pub. Date: Oct. 30, 2014

(54) Photodiode for Topside and Backside Illumination

(71) Applicant: BROADCOM CORPORATION, Irvine, CA (US)

(72) Inventors: Donald Edward Major, Irvine, CA (US); Chih-Chieh Shen, Irvine, CA (US)

(73) Assignee: Broadcom Corporation, Irvine, CA (US)

(21) Appl. No.: 13/872,313

(22) Filed: Apr. 29, 2013

(51) Int. Cl. H01L 31/105; H01L 31/18

(52) U.S. Cl. CPC H01L 31/105; H01L 31/18
USPC 257/458; 438/87

(57) ABSTRACT

A photodiode structure provides light sensitivity to both front side and backside illumination. The photodiode may include a deep N well (DNW) that extends over a Psub substrate. The DNW may be discontinuous, or may extend continuously over the Psub substrate. Additional DNW area under the diode area proportionally increases the sensitivity to backside illumination. In addition, the photodiode may use a lightly doped anode region to increase the depletion region between the anode region and the deep N well. The anode region may be lightly doped Psub, as opposed to Pwell, in order to increase the topside light sensitive area percentage of the total area. One highly sensitive implementation uses Psub doping in the anode region, and a deep N well under the entire diode. This provides maximum areal density of the diode intrinsic regions nearest the wafer backside.

### TECHNICAL FIELD

This disclosure relates to photodiodes.

### BACKGROUND

Rapid advances in semiconductor manufacturing techniques, driven by immense customer demand over several decades, have resulted in an enormous market for electronic devices. In some electronic devices, photodiodes act as sensors of incident light, e.g., in the visible, infrared, or other spectrums. Improvements in photodiodes will help facilitate the continued development and adoption of electronic light sensitive devices.

### BRIEF DESCRIPTION OF THE DRAWINGS

The innovation may be better understood with reference to the following drawings and description. In the figures, like reference numerals designate corresponding parts throughout the different views.

FIG. 1 shows an example of device exposed to backside and topside illumination.

FIG. 2 is an example section of a photodiode array layout.

FIG. 3 is an example cross section of a photodiode.

FIG. 4 is an example cross section of a photodiode showing depletion regions.

FIG. 5 shows an example of dimensions for the structure of the photodiode.

FIG. 6 shows an example of a photodiode using Pwell anodes.

FIG. 7 shows an example of a photodiode using a discontinuous N well.

FIG. 8 shows an example of a photodiode without a deep N well (DNW).

FIG. 9 shows an example test circuit for a photodiode.

FIG. 10 shows an example of a topside illumination sensitivity measurement.

FIG. 11 shows an example of a backside illumination sensitivity measurement.

FIG. 12 shows an example fabrication method.

### DETAILED DESCRIPTION

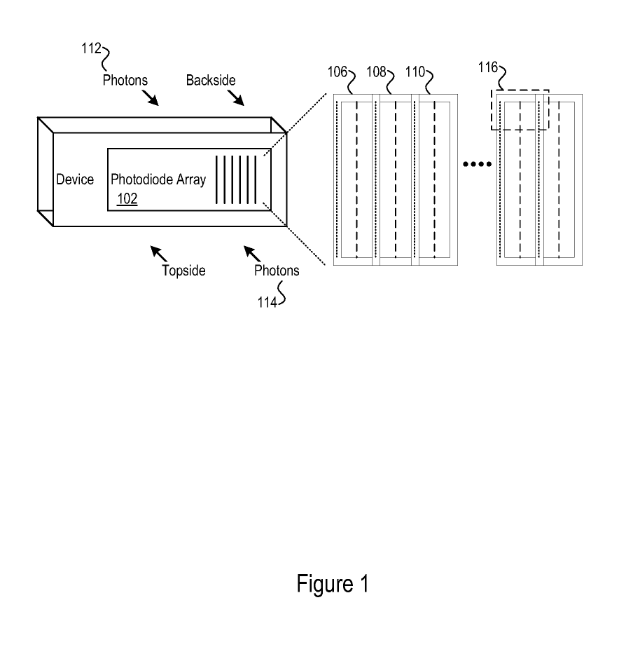

FIG. 1 shows a device 100 exposed to backside and topside illumination. The device may be virtually any type of electronic device, such as a cell phone, a sensor in a manufacturing process line, a digital camera, or any other type of device that includes light sensing capability. To that end, the device 100 includes an illumination sensor. In this example, the illumination sensor is a photodiode array 102. The photodiode array 102 may be implemented in many different ways. As one example, the photodiode array 102 may be an organization of multiple photodiodes into tiles, such as the tiles 106, 108, and 110. However, the illumination sensor may have any number of photodiodes (even a single photodiode) arranged in any desired manner. As will be explained in detail below, the photodiodes are sensitive to both frontside illumination 112 and backside illumination 114, which permits the device 100 to sense illumination from both directions.

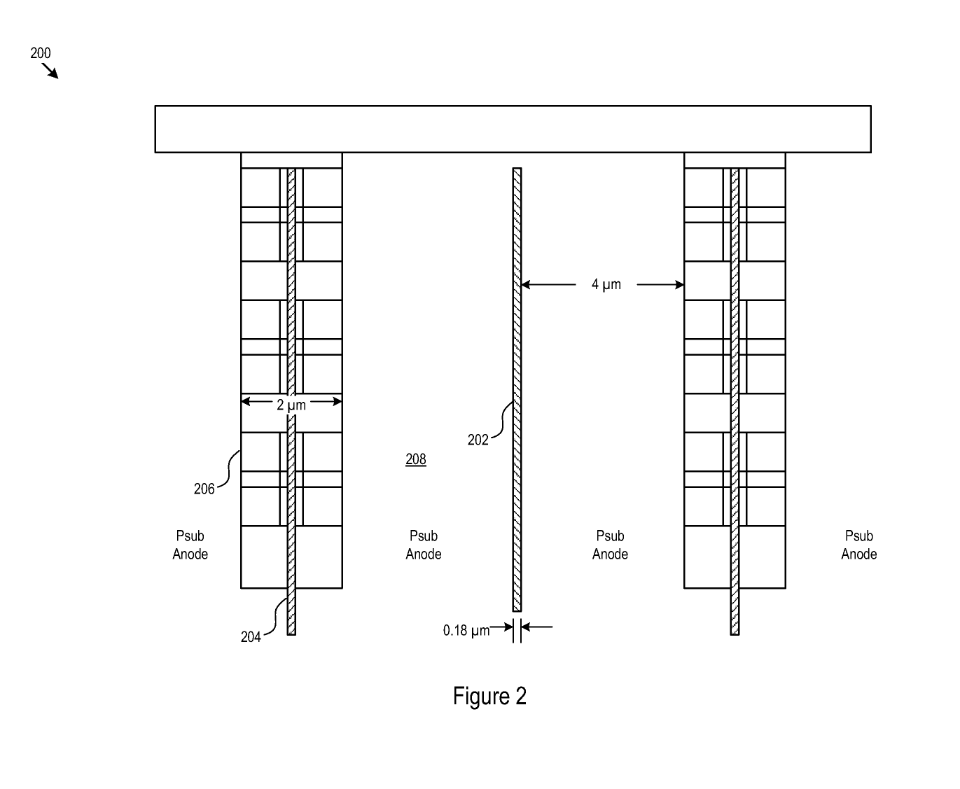

FIG. 2 is an example section 200 of a photodiode array layout taken from the area 116 shown in FIG. 1. The photodiodes may be fabricated using a standard CMOS process, e.g., a standard 40 nm CMOS process. The section 200 shows a P+ stripe 202 for anode contacts and an N+ stripe 204 for cathode contacts. The section 200 also shows several example Nwell areas, one of which is labeled 206, and several areas where Psub anodes exist e.g., area 208. The size, shape, and location of any of the elements of the photodiode layout may vary widely, according to the particular implementation desired. As just one example, the Nwells may be approximately 2 microns (2 μm) wide, there may be approximately 4 μm separation between the P+ stripes 202 and the Nwells, and the P+ stripes 202 and the N+ stripes 204 may be 0.18 μm wide.

Further, any array of multiple photodiodes may vary widely in size and shape. As just one example, an array may be approximately 123 μm wide and 58 μm high, using 13 tiled repetitions of cathode and anode regions. More specifically, the array may include 13 tiled repetitions of 2 μm×58 μm Nwell cathode regions, and 12 repetitions of 0.18×58 μm anode P+ stripes, e.g., one between each pair of Nwell cathode regions. However, this is just one example, and the photodiodes in a photodiode array may be fabricated over an extensive range of dimensions for any structural features described below.

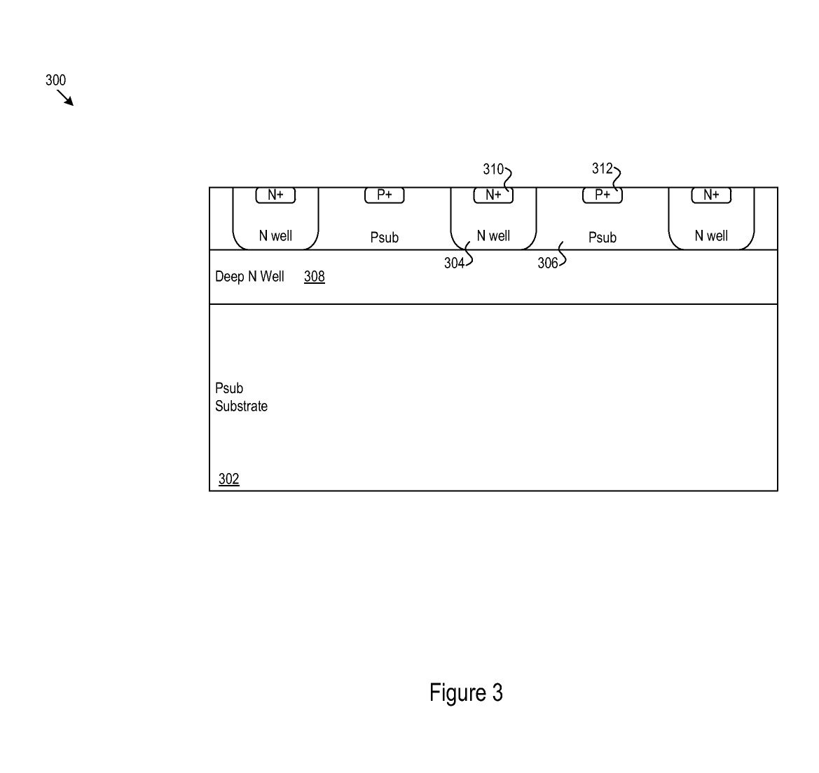

FIG. 3 is an example cross section of a photodiode 300. The photodiode 300 is built on a Psub substrate 302. The photodiode 300 includes a cathode region 304 and an anode region 306 adjacent to the cathode region 304. The anode region 306 may comprise, e.g., a Psub doping profile. The Psub doping profile has a lighter doping concentration than, e.g., a Pwell doping profile defined within a common fabrication process that specifies both the Psub doping profile and the Pwell doping profile. As examples, the Psub doping may be 100-1000 times less concentrated than the Pwell doping. The cathode region 304 may comprise, e.g., an Nwell doping profile defined within the fabrication process.

As noted above, a standard CMOS process may be used to fabricate the photodiode. However, other standard fabrication processes, or custom fabrication processes, may also create the photodiode using the structures described below. Furthermore, it was noted above that the anode region doping may be relatively light (e.g., 100 to 1000 times) compared to other doping profiles. However, the anode region doping concentration may be less than or greater than 100 to 1000 times less than the concentration provided by other doping profiles. One benefit of the light doping (e.g., Psub doping) is for increased sensitivity to both topside and backside incident light. The doping concentration chosen may depend on the desired sensitivity to light of the photodiode, and in turn, on the desired width of the depletion region formed by the anode region and a deep N well region.

In that respect, the photodiode 300 includes a depletion region inducing Nwell 308 above the Psub substrate 914 and under the anode region 306 and the cathode region 304. The N well 308 is referred to as a deep N well (DNW) 308, but it need not be limited to any specific depth. Instead, the DNW 308 is buried within the device and interacts with the Psub substrate 302 and the Psub anode regions 306 to create additional depletion regions that would not ordinarily be present without the DNW 308. One benefit of the buried DNW is for increased sensitivity to backside light. The DNW 308 may be continuous or discontinuous, as will be explained below.

The photodiode 300 may include ohmic contacts. For example, highly doped N+ contacts 310 may be fabricated in the cathode regions 304. Similarly, highly doped P+ contacts 312 may be fabricated in the anode regions 306. The contacts facilitate connection to additional fabrication layers, such as metal layers, that connect the anode and cathode to device pins, for example.

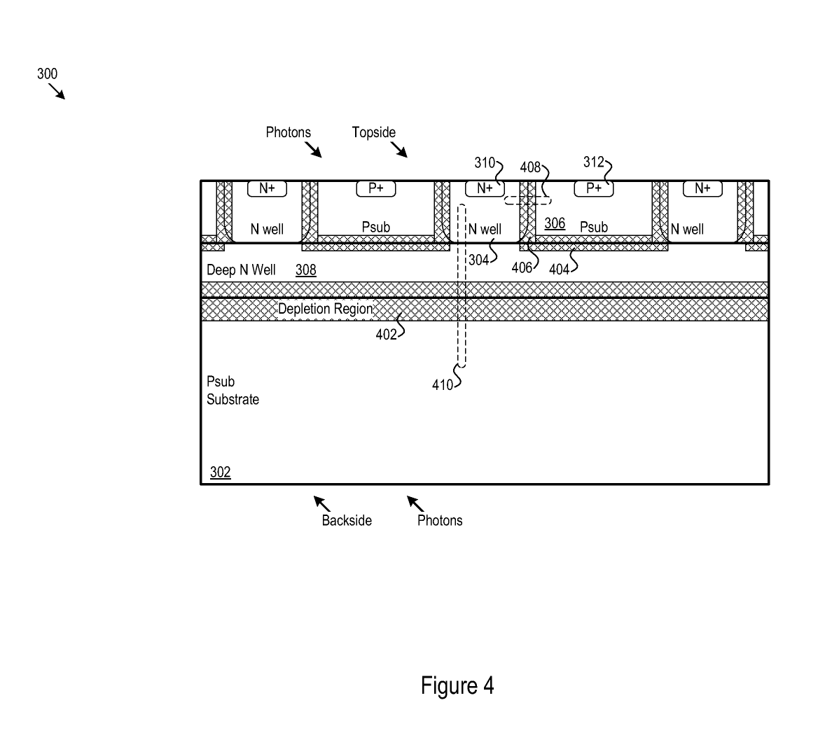

FIG. 4 is another example cross section of the photodiode 300, with depletion regions illustrated. In particular, the DNW 308 results in buried depletion regions. For example, a buried (backside) depletion region 402 exists between the DNW 308 and the Psub substrate 302. The DNW 308 also results in a buried, near top surface (topside) depletion region 404 between the DNW 308 and the anode region 306 (a buried depletion region under the anode regions). Note that the anode-cathode depletion regions 406 are also present, and extend to the top surface of the diode structure, and down into the DNW 308. The anode region 306, anode-cathode depletion region 406, and cathode region 304 form a lateral PiN (Positive, intrinsic or neutral, Negative) diode structure 408. The Psub substrate 302, depletion region 402, and cathode regions 304 form a vertical PiN diode structure 410. The DNW 308 creates the buried (vertical) PiN structures that increase the sensitivity to photons from the backside.

As noted above, the Psub anodes 306 may be more lightly doped than Pwell created with the same process. The difference in doping concentration may be, as one example, on the order of 100 to 1000. The lighter doping of the Psub anodes 306 results in a wider depletion region 404. The wider depletion regions extend further into the device and as a result, give increased sensitivity to light.

In particular, the backside depletion region 402 may provide sensitivity to light impinging from the backside of the substrate 302. These photons pass through the relatively optically transparent Psub substrate 302. The photons that reach the backside depletion region 402 interact with the depletion region to generate charge carriers that result in current vertically through the diode. Also, photons from the topside interact with the topside depletion region 404 and anode-cathode depletion regions 406, and also generate current laterally through the diode.

Note that the designations of topside and backside are for ease of reference only. Either side may be considered the topside or backside. Regardless of designation, the diode 300 exhibits light sensitivity from different sides.

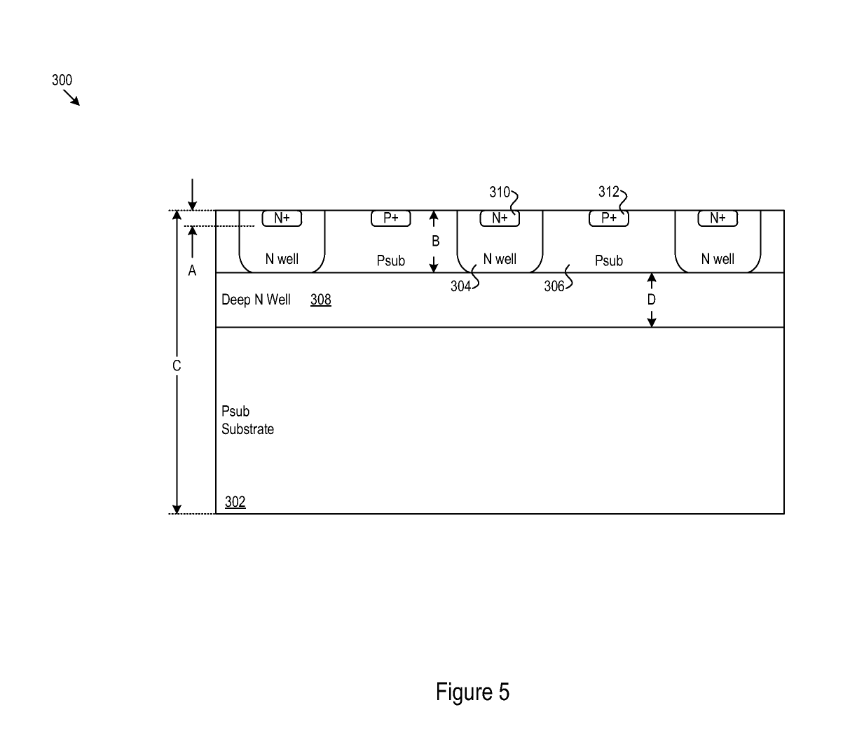

FIG. 5 shows an example of dimensions for the fabricated photodiode structures. Dimension A refers to the penetration depth of N+ and P+ into the wafer from the top surface. 100 nanometers (nm) is typical for dimension A. Dimension B refers to the penetration depth of Nwell and Psub (or Pwell) anode and cathode regions into the wafer from the top surface until they reach the DNW 308. 500 nm is typical for dimension B. Dimension C refers to the wafer thickness. 780 μm typical for dimension C, and in cases where backgrinding is used, this thickness may be reduced, e.g., to 310 μm. Additional backgrinding or another material removal process may be employed to further reduce the thickness for increased optical transparency. Dimension D refers to the DNW 308 thickness. 1000 nm is typical for dimension D. The dimensions in FIG. 5 are examples only; the photodiode may be fabricated over an extensive range of dimensions for any of the features noted above.

Several alternate constructions for a photodiode are discussed next. Some example performance data then follows.

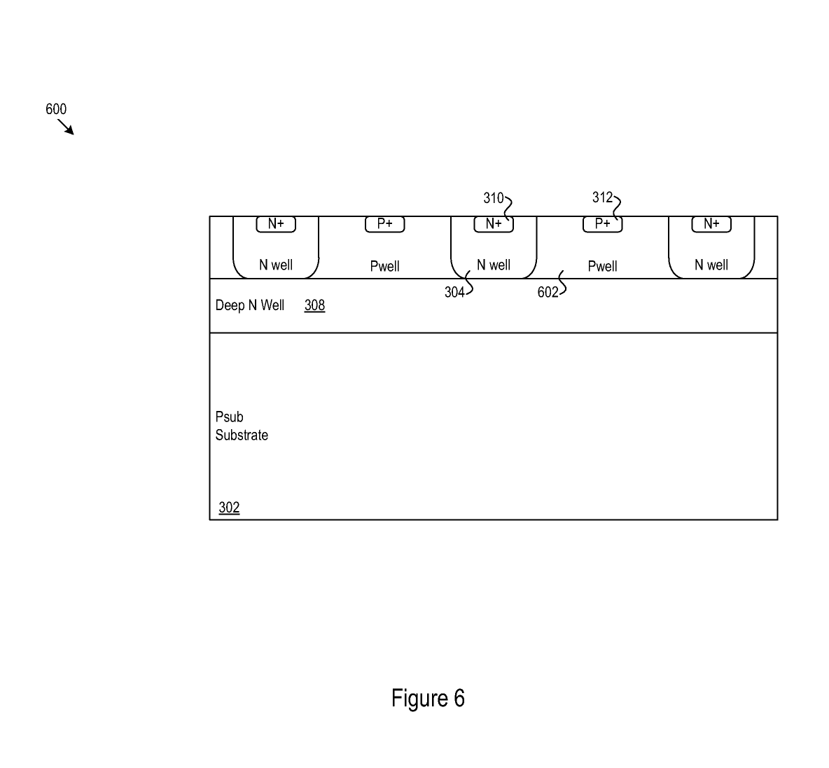

FIG. 6 shows an example of a photodiode 600 using Pwell anodes. In FIG. 6, the diode retains the DNW 308. However, the Psub doping profile anodes are replaced with Pwell doping profile anodes 602.

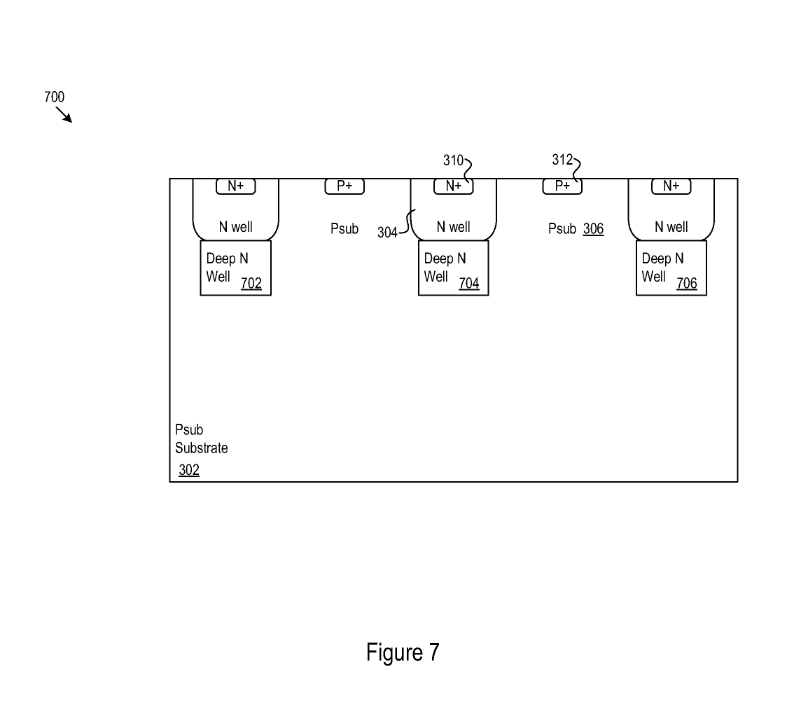

FIG. 7 shows an example of a photodiode 700 using discontinuous DNW. In other words, the DNW need not run the entire length of the Psub substrate 302, nor be present under all of the anode regions and all of the cathode regions. Instead, the DNW may be selectively present under all or part of any anode regions, cathode region, or both regions. In particular, FIG. 7 shows several examples of discontinuous DNW: the physically separate DNW regions 702, 704, and 706. In the example of FIG. 7, the DNW is present under the cathode regions 304, and omitted under the anode regions 306. Note that with discontinuous DNW, both lateral and vertical PiN structures still form in the photodiode 700.

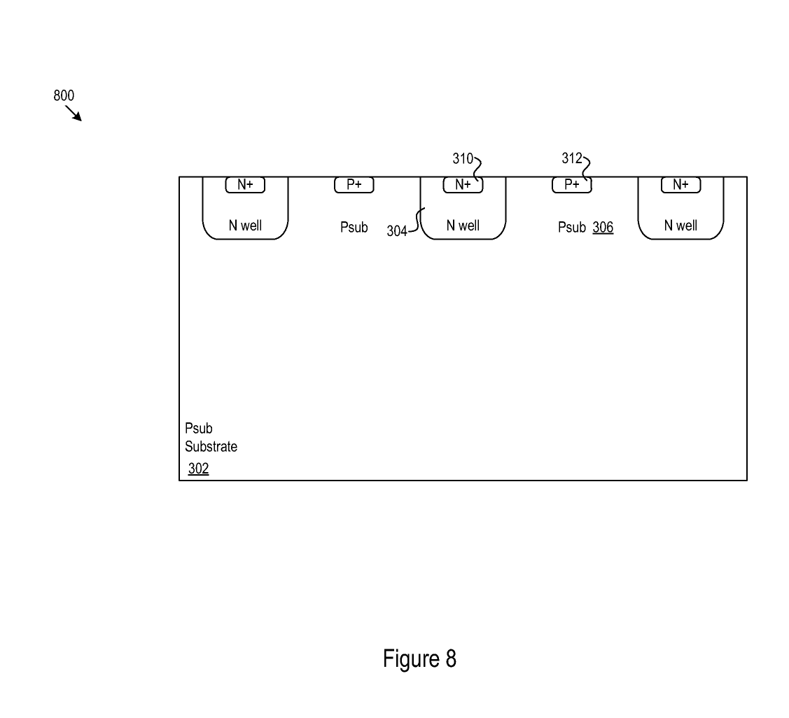

FIG. 8 shows another example of a photodiode 800. In the example of FIG. 8, the anode regions 306 are Psub regions. However, no DNW is present.

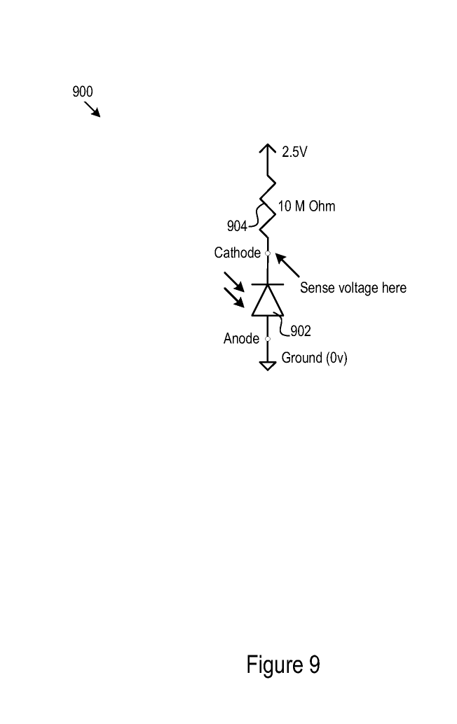

FIG. 9 shows a test circuit 900 for a photodiode such as those described above. In FIG. 9, a photodiode 902 is connected to ground at the anode. The photodiode 902 is also connected through a pullup resistor 904 to a reference voltage. In this example, the pullup resistor is 10 M Ohms, and the reference voltage is 2.5 V.

The test circuit 900 may be used to test the photodiode sensitivity to illumination from one or multiple sides. Some test results are noted next. Table 1 summarizes twelve different photodiode structures used in the tests. The photodiode matrix in Table 1 represents a selection of anode structures from the first column, and different DNW structures from the last three columns. For example, photodiode 1 has a Pwell anode and no DNW, while photodiode 9 has a Psub anode, no Pwell under the P+ contact, and continuous DNW.

TABLE 1
Photodiode Structural Variations

| | DNW structural options | | |
|---|---|---|---|
| | | | DNW under |
| Anode | | DNW under | both anode |
| structural | | Nwell only | and cathode |
| options are | | (discontinuous | (continuous |
| below | No DNW | DNW) | DNW) |
| Anode is | Diode 1 | Diode 2 | Diode 3 |
| Pwell | Layout: Lateral | Layout: Lateral | Layout: Lateral |
| Anode is | Diode 4 | Diode 5 | Diode 6 |
| Psub, with | Layout: Lateral | Layout: Lateral | Layout: Lateral |
| Pwell under | | | |
| P+ contact | | | |
| region | | | |
| Anode is | Diode 7 | Diode 8 | Diode 9 |
| Psub, with | Layout: Lateral | Layout: Lateral | Layout: Lateral |
| no Pwell | | | |
| under P+ | | | |
| contact area | | | |
| | Additional Diodes | | |
| | DNW structural options | | |
| Anode | | DNW under | Variant of |
| structure | No DNW | Nwell only | Diode 3 |
| Anode is | Diode 10 | Diode 11 | Diode 12 |
| Psub, with | Layout: Vertical | Layout: Vertical | Diode 12 is a |
| no Pwell | | | copy of Diode |
| under P+ | | | 3 with ESD |
| contact area | | | protection |
| | | | diodes connected. |

The two vertical layouts (diode 10 and diode 11) are differently shaped. The vertical layout diodes have larger rectangular area cathodes and anodes than the lateral photodiodes. The lateral photodiodes (diodes 1-9, and 12) have the general layout illustrated in FIGS. 3-8, with a narrow-striped design.

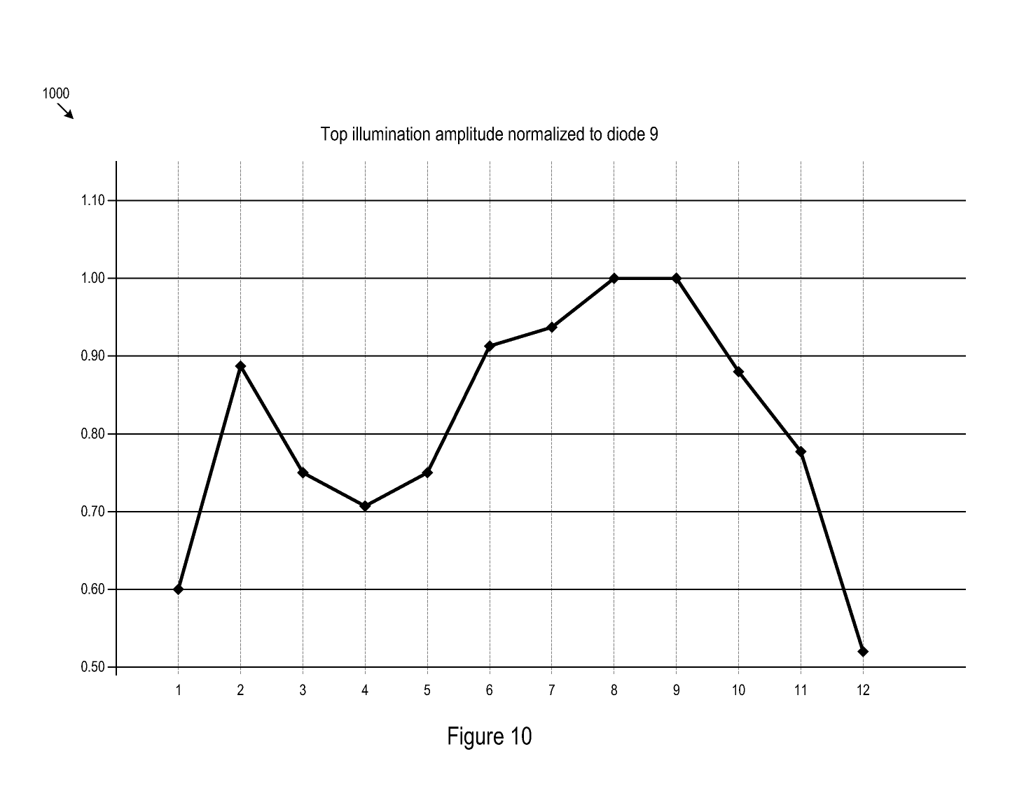

FIG. 10 shows an example of topside illumination sensitivity 1000 for diodes 1-12. The diode number is plotted on the x-axis, and sensitivity as measured by the test circuit 900, and normalized with respect to diode 9, is plotted on the y-axis. Diodes 8 and 9 show the best response from the topside.

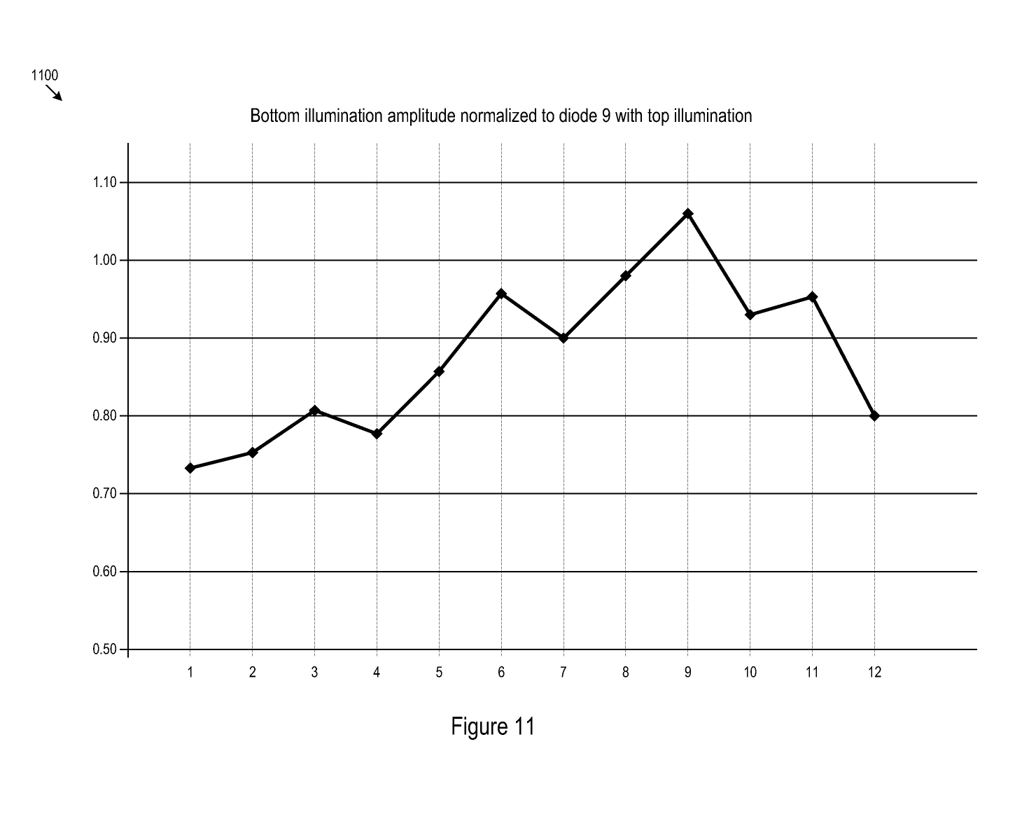

FIG. 11 shows an example of backside illumination sensitivity 1100 for diodes 1-12. Again, the diode number is plotted on the x-axis, and output voltage from the test circuit 900 is plotted on the y-axis, normalized with respect to diode 9 with top illumination. Diode 9 shows the best response from the backside.

Different photodiode structures may be chosen for an application according to the sensitivity desired from the topside and the backside. Photodiode 9, for example, provides the best sensitivity for backside illumination and (along with photodiode 8) has the best sensitivity to topside illumination. The sensitivity of photodiode 9 results from the Psub anodes and the continuous DNW under the device, for maximum areal density of diode intrinsic regions nearest the wafer backside.

Of course, other photodiode structures may be used in other applications. Note that photodiodes 10 and 11 exhibit reduced sensitivity to topside illumination, and this may be a benefit in certain applications. In part the reduced sensitivity is due to lower areal density of the diode intrinsic regions near the topside. Photodiode 3 uses a Pwell anode (which is more highly doped than Psub), and therefore the intrinsic regions are shorter, resulting in less sensitivity because a lower percentage of incident light will fall into the intrinsic regions.

In contrast, photodiode 8 uses Psub anodes and a discontinuous DNW (e.g., DNW under the cathodes only). Photodiode 8 is the most sensitive to topside illumination (along with photodiode 9), but has reduced sensitivity compared to photodiode 9 to backside illumination. As another example, photodiode 7 uses Psub anodes, but no DNW. The result is a mild reduction is topside illumination sensitivity, and a reduction in backside illumination sensitivity.

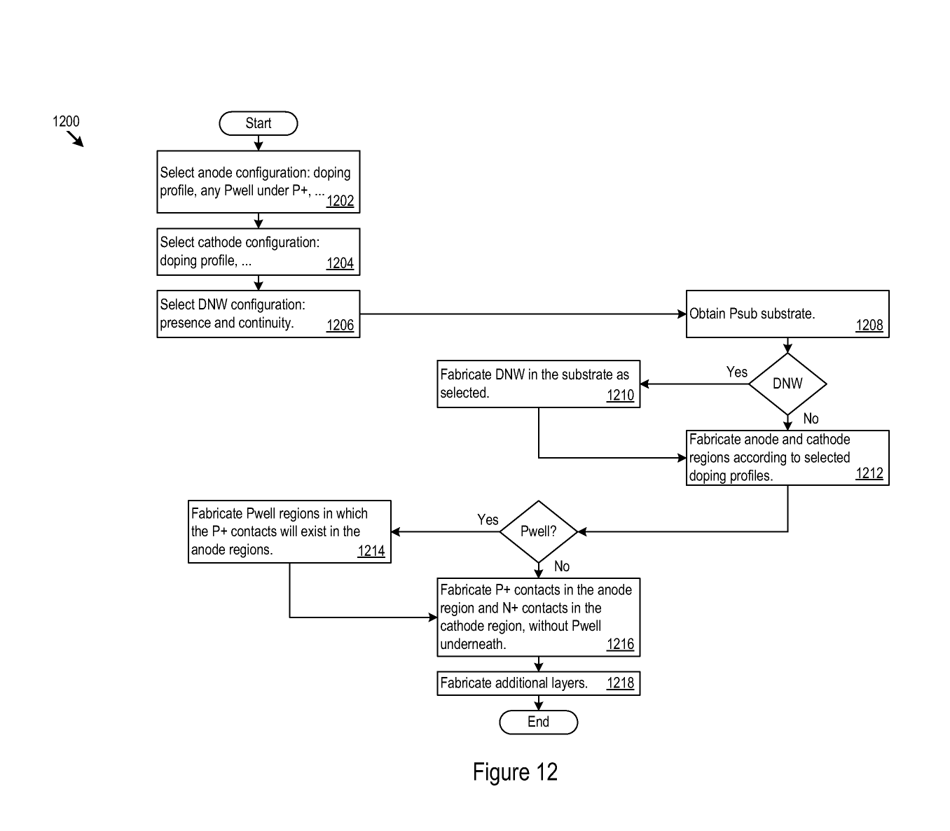

FIG. 12 shows an example fabrication method 1200 for a photodiode. The method 1200 includes selecting the anode configuration (1202). Several design options may be decided among for the anode regions, as examples: the doping profile (e.g., Psub or Pwell) and whether to include any Pwell under the P+ ohmic contacts. Similarly, the cathode region configuration is determined (1204), including its doping profile (e.g., Nwell). In addition, the configuration of the DNW is determined (1206). For example, the DNW may be present or omitted altogether. Also, when present, the DNW may be continuous or discontinuous, being present under all or part of one or more anodes and cathodes or being present, e.g., all along the Psub substrate 302.

The parameters chosen in 1202-1206 may vary from diode to diode in an array of multiple diodes. As just two examples, some diodes in a diode array may have a Psub doping profile without DNW under the anode, while other diodes may have a Psub doping profile with Pwell regions under the P+ contacts and DNW extending continuously under the anode regions and the cathode regions. Table 1 shows other combinations of characteristics, and other combinations may be fabricated with varying levels of sensitivity.

Once the substrate is obtained (1208), fabrication of the DNW may take place (1210) according to any selected DNW options selected. For example, discontinuous DNW may be fabricated by creating DNW only below where Nwell cathode regions will be situated. Alternatively, continuous DNW may be fabricated by creating DNW below where both anode and cathode regions will be situated, or along the entire Psub substrate.

Regardless of whether DNW is present, anode and cathode regions for the diode are fabricated (1212). The anodes and cathodes are fabricated according to their selected doping profiles. This may result in, for example, Psub or Pwell anode regions.

The fabrication method also creates ohmic contacts. For the anode regions, optional Pwell may be added into the anode regions first (1214). The Pwell may extend a selected distance (typically a somewhat short distance) below the P+ contacts. The P+ and N+ contacts may then be created in the anode regions and the cathode regions (1216). In addition, any additional fabrication steps may take place (1218). The additional fabrication steps may add, for example, metal or polysilicon layers for additional circuitry and interconnections, including interconnections of the diodes to test points, terminals, device pins, or other access points.

While various embodiments of the invention have been described, it will be apparent to those of ordinary skill in the art that many more embodiments and implementations are possible within the scope of the invention. Accordingly, the invention is not to be restricted except in light of the attached claims and their equivalents.

What is claimed is:

1. A photodiode comprising:
an anode region comprising a Psub doping profile;
a cathode region adjacent to the anode;
a substrate; and
an N well region between the substrate and the anode and cathode regions, the N well region configured to create a depletion region below the cathode region.

2. The photodiode of claim 1, where:
the N well region is continuous under the anode region and the cathode region.

3. The photodiode of claim 1, where:
the N well region is discontinuous.

4. The photodiode of claim 3, where the N well region is present under the cathode region, but not under the anode region.

5. The photodiode of claim 3, where:
the N well region results in a vertical positive—intrinsic—negative (PiN) diode formed from the substrate, depletion region, and cathode region.

6. The photodiode of claim 3, where:
the N well region is discontinuous along the substrate.

7. The photodiode of claim 1, further comprising:
a P+ contact area in the anode region; and
Pwell under the P+ contact area.

8. The photodiode of claim 1, where the Psub doping profile comprises P-type doping at least 100 times weaker than P-type doping for a Pwell region.

9. The photodiode of claim 1, where the Psub doping profile comprises P-type doping at least 1000 times weaker than P-type doping for a Pwell region.

10. A method comprising:
forming, according to a selected fabrication process, an anode region having a light P-type doping profile compared to a Pwell doping profile in the selected fabrication process;
forming a cathode region adjacent to the anode region;
forming an N well region between a substrate and the anode and cathode regions, so that the N well creates a depletion region under the anode region and the cathode region.

11. The method of claim 10, where forming an anode region comprises:
forming a Psub anode region.

12. The method of claim 10, where forming comprises: forming the anode region with a light P-type doping profile that has at least 100 times less concentration than the Pwell doping profile.

13. The method of claim 10, where forming comprises: forming the anode region with a light P-type doping profile that has at least 1000 times less concentration than the Pwell doping profile.

14. The method of claim 10, where forming an N well region comprises:
forming a discontinuous N well region under the anode region and the cathode region.

15. The method of claim 10, where forming an N well region comprises:
forming a discontinuous N well region under the anode region and the cathode region by creating the N well under the cathode region and not under the anode region.

16. The method of claim 10, where forming an N well region comprises:
forming a continuous N well region under the anode region and the cathode region.

17. The method of claim 10, where forming an anode region further comprises:
forming an ohmic contact in the anode region.

18. The method of claim 17, further comprising:
forming a Pwell under the ohmic contact.

19. A photodiode comprising:
a Psub substrate;
a cathode region;
an anode region adjacent to the cathode region, the anode region comprising a Psub doping profile that has a lighter doping concentration than a Pwell doping profile within a common fabrication process that defines both the Psub doping profile and the Pwell doping profile;
a deep N well in the Psub substrate and under the anode region and the cathode region, the deep N well resulting in:
a buried depletion region between the deep N well and the Psub substrate;
a top surface depletion region between the deep N well and the cathode region.

20. The photodiode of claim 19, where:
the Psub doping profile has a lighter doping concentration by a factor of at least 100; and
the deep N well extends continuously under both the anode region and the cathode region.
